(19) United States
(12) Patent Application Publication
(10) Pub. No.: US 2019/0323970 A1
(43) Pub. Date: Oct. 24, 2019

(54) SENSING METHOD, SENSOR AND METHOD OF MANUFACTURING THE SAME

(71) Applicant: National Taiwan University of Science and Technology, Taipei City (TW)

(72) Inventors: Jinn P. CHU, Taipei City (TW); Chien-Kuang CHEN, Taipei City (TW)

(21) Appl. No.: 16/140,889

(22) Filed: Sep. 25, 2018

(30) Foreign Application Priority Data
Apr. 24, 2018 (TW) 107113923
Jul. 12, 2018 (TW) 107124058

(51) Int. Cl. G01N 21/77

(52) U.S. Cl. CPC G01N 21/77; C23C 14/042

(57) ABSTRACT

A method of manufacturing a sensor comprises: providing a substrate; forming a photoresist layer on the substrate, wherein the photoresist layer comprises a hole array which comprises a plurality of holes which pass through from one side of the photoresist layer to the substrate; sputtering a metallic glass material on the photoresist layer to deposit the metallic glass material on a hole wall of each hole and a part of the substrate defined by the hole wall; removing the photoresist layer and forming a nanotube array structure of the metallic glass material, wherein the nanotube array structure comprises a plurality of nanotubes, and each nanotube has an open end opposite to the substrate; performing a surface treatment on the nanotube array structure to form a plurality of functional groups in each nanotube; and anchoring a plurality of aptamers in each nanotube by activating the plurality of functional groups.

### CROSS-REFERENCE TO RELATED APPLICATION

This application claims the priority benefits of Taiwan Patent Application Nos. 107113923, filed on Apr. 24, 2018, and 107124058, filed on Jul. 12, 2018, the entirety of which is hereby incorporated by reference herein and made a part of this specification.

### BACKGROUND OF THE INVENTION

### 1. Field of the Invention

The present disclosure generally relates to a sensor, and more particularly to a sensor with a nanotube array structure. The present disclosure further comprises a method of manufacturing the sensor and a sensing method for the sensor.

### 2. Description of Related Art

Currently, biosensors are widely used in areas such as in medicine, environmental protection, food, and microbial or viral detection to sense targets having biometric components. These biosensors can be roughly classified into optical biosensors, electrochemical biosensors, and piezoelectric biosensors according to their different operating principles. In the case of the optical biosensor, a beam is projected to the surface of the sensor to detect the property of the reflected light by adjusting the property of the incident light, so as to determine whether the targets to be sensed have attached on the surface of the sensor and to conduct further analysis of the targets. However, to satisfy the different needs in use, an important focus of current research is the improvement of the surface of the biosensor to enhance both the attachment of the targets to the surface of the biosensor and the optical properties of the surface of the biosensor.

### SUMMARY OF THE INVENTION

A primary object of this disclosure is to provide a method of manufacturing a sensor with enhanced properties of the surface of the sensor that improve both the attachment of a target and the optical properties effectively.

To achieve the aforesaid and other objects, the method of manufacturing the sensor of this disclosure comprises: providing a substrate; forming a photoresist layer on the substrate, wherein the photoresist layer comprises a hole array, and the hole array comprises a plurality of holes which pass through from one side of the photoresist layer to the substrate; sputtering a metallic glass material on the photoresist layer to deposit the metallic glass material on a hole wall of each hole and a part of the substrate defined by the hole wall; removing the photoresist layer and forming a nanotube array structure of the metallic glass material, wherein the nanotube array structure comprises a plurality of nanotubes, and each nanotube has an open end opposite to the substrate; performing a surface treatment on the nanotube array structure to form a plurality of functional groups in each nanotube; and anchoring a plurality of aptamers in each nanotube by activating the plurality of functional groups.

In one embodiment of this disclosure, an inner surface of each nanotube is modified by a solution of 0.1 wt % to 10 wt % 3-aminopropyltriethoxysilane in methanol to form the plurality of functional groups when the surface treatment is performed.

In one embodiment of this disclosure, the plurality of functional groups are activated by a solution containing 1-ethyl-3-(3-dimethylaminopropyl)carbodiimide and N-hydroxysuccinimide, and the plurality of aptamers are combined with the plurality of functional groups by adding a 2 wt % to 20 wt % buffer solution of the plurality of aptamers.

In one embodiment of this disclosure, the plurality of aptamers are antibodies, DNA probes, or biotins.

In one embodiment of this disclosure, the method further comprises: filling targets to be sensed into the plurality of nanotubes after the plurality of aptamers have been anchored.

Another object of this disclosure is to provide the sensor. The sensor of this disclosure comprises a substrate, a nanotube array structure and a plurality of aptamers. The nanotube array structure is formed on one side of the substrate. The nanotube array structure comprises a plurality of nanotubes, and each nanotube has an open end opposite to the substrate. The plurality of aptamers are anchored in the plurality of nanotubes, which are processed by surface activation.

In one embodiment of this disclosure, a wall thickness-to-diameter ratio of each nanotube ranges from 1:2 to 1:10.

In one embodiment of this disclosure, a height-to-width ratio of each nanotube ranges from 1:0.5 to 1:10.

In one embodiment of this disclosure, a duty ratio of the plurality of nanotubes ranges from 0.5 to 6.

In one embodiment of this disclosure, the nanotube array structure comprises an ordered array composed of the plurality of nanotubes, and a diameter of each nanotube ranges from 10 nm to 100 μm.

In one embodiment of this disclosure, a diffractive reflectance intensity of the nanotube array structure for transverse electric polarization and transverse magnetic polarization is increased with an increase in the diameter of each nanotube.

In one embodiment of this disclosure, the nanotube array structure comprises at least one material selected from the group consisting of: a zirconium-based metallic glass, a titanium-based metallic glass, a palladium-based metallic glass, an iron-based metallic glass, a copper-based metallic glass, a nickel-based metallic glass, an aluminium-based metallic glass, a tungsten-based metallic glass, and a magnesium-based metallic glass.

Another object of this disclosure is to provide the sensing method for the sensor. The sensing method of this disclosure comprises: placing the sensor in a fluid with targets to be sensed; projecting an incident light to the nanotube array structure of the sensor from a light source and receiving a reflected light of the incident light; and analyzing an optical property of the reflected light to determine a sensing result of the targets to be sensed.

In one embodiment of this disclosure, the optical property is associated with a reflection angle of the reflected light with maximum reflectivity.

In one embodiment of this disclosure, the optical property is associated with a color of the reflected light.

### BRIEF DESCRIPTION OF THE DRAWINGS

The accompanying drawings are included to provide a further understanding of the invention and are incorporated in and constitute a part of this specification. The drawings illustrate embodiments of the invention and, together with the descriptions, serve to explain the principles of the invention.

FIG. 1 illustrates a structural configuration of a sensor of this disclosure;

FIG. 2 illustrates a flowchart of a method of manufacturing a sensor of this disclosure;

FIG. 3 illustrates a structural configuration corresponding to each step of the method of manufacturing the sensor of this disclosure;

FIG. 4 illustrates a flowchart of a sensing method of this disclosure;

FIG. 5 illustrates an embodiment of the sensing method of this disclosure;

FIG. 6 illustrates incident angles of light and reflectances corresponding to different comparative examples and experimental examples measured by the sensing method of this disclosure;

FIG. 7 illustrates chromaticity of the reflected lights corresponding to different comparative examples and experimental examples measured by the sensing method of this disclosure; and

FIG. 8 illustrates chromaticity of the reflected lights corresponding to different concentrations of streptavidin measured by the sensing method of this disclosure.

### DESCRIPTION OF THE EMBODIMENTS

Since various aspects and embodiments are merely exemplary and not limiting, after reading this specification, skilled artisans will appreciate that other aspects and embodiments are possible without departing from the scope of the disclosure. Other features and benefits of any one or more of the embodiments will be apparent from the following detailed description and the claims.

As used herein, the terms “comprises,” “comprising,” “includes,” “including,” “has,” “having” or any other variation thereof are intended to cover a non-exclusive inclusion. For example, a component, structure, article, or apparatus that comprises a list of elements is not necessarily limited to only those elements but may include other elements not expressly listed or inherent to such component, structure, article, or apparatus.

As used herein, the term “anchoring” refers to an object forming a molecular bond with another object. The term “aptamer” refers to a biomolecule, e.g. antibody, DNA probe, biotin, etc., which is capable of forming a molecular bond with a target to be sensed. The term “modified” refers to a surface treatment performed on an object by a medium to change the surface properties of the object.

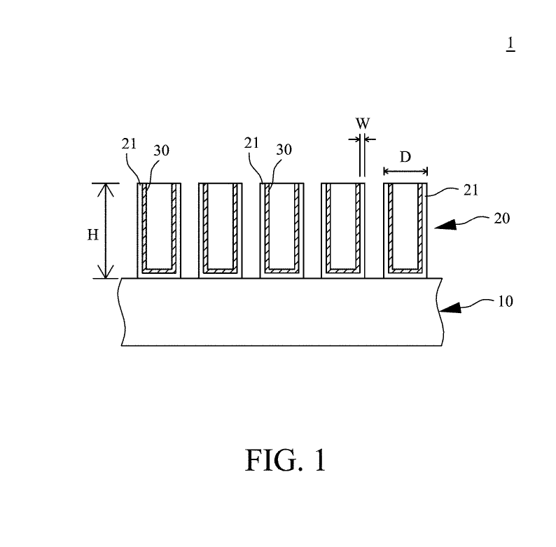

Refer to FIG. 1, which illustrates a structural configuration of a sensor of this disclosure. As illustrated in FIG. 1, the sensor 1 of this disclosure comprises a substrate 10, a nanotube array structure 20 and a plurality of aptamers 30. In one embodiment of this disclosure, the substrate 10 may comprise a silicon wafer, but the substrate 10 may also comprise a III-V semiconductor, glass, quartz, sapphire or the like. The substrate 10 may further comprise plastic or other polymer materials. The material of the substrate 10 is selected depending on different needs, but this disclosure is not limited thereto. In addition, the substrate 10 may be polished before the formation of the nanotube array structure 20.

The nanotube array structure 20 is formed on one side of the substrate 10. The nanotube array structure 20 comprises a plurality of nanotubes 21. An ordered array is composed of a plurality of nanotubes 21. Here, the term “ordered” refers to the plurality of nanotubes 21 being all oriented at the same direction and arranged by a fixed and repetitive periodicity to facilitate diffraction due to an incident light. Each nanotube 21 comprises a hollow tube. One end of each nanotube 21 is connected to the substrate 10 to form a closed end, and each nanotube 21 has an open end having an opening opposite to the substrate 10. Each nanotube 21 has a diameter D, a height H, and a wall thickness W. In one embodiment of this disclosure, the diameter D of each nanotube 21 ranges from 10 nm to 100 μm, and the preferred range is from 500 nm to 800 nm. A height-to-width ratio (H:D) of each nanotube 21 ranges from 1:0.5 to 1:10. A wall thickness-to-diameter ratio (W:D) of each nanotube 21 ranges from 1:2 to 1:10. A fixed distance is defined between any two adjacent nanotubes 21 of the plurality of nanotubes 21. In one embodiment of this disclosure, a duty ratio of the plurality of nanotubes 21 ranges from 0.5 to 6. In other words, a minimum distance between any two adjacent nanotubes 21 is 0.5 times the diameter D of a nanotube 21, and a maximum distance between any two adjacent nanotubes 21 is 6 times the diameter D of the nanotube 21, but this disclosure is not limited thereto. The preferred duty ratio of the plurality of nanotubes 21 ranges from 0.5 to 2.

Here, the nanotube array structure 20 may comprise a metallic glass material. The metallic glass material comprises at least one material selected from the group consisting of: a zirconium-based metallic glass, a titanium-based metallic glass, a palladium-based metallic glass, an iron-based metallic glass, a copper-based metallic glass, a nickel-based metallic glass, an aluminium-based metallic glass, a tungsten-based metallic glass, and a magnesium-based metallic glass, but this disclosure is not limited thereto. In one embodiment of this disclosure, the zirconium-based metallic glass comprises 37-66 at % zirconium. For example, the zirconium-based metallic glass may comprise a ZrAlCo metallic glass (Zr: 54-60 at %, Al: 13-22 at % and Co: 18-30 at %), a ZrCuAlNi metallic glass (Zr: 48-66 at %, Cu: 7-30 at %, Al: 8-12 at % and Ni: 5-18 at %), a ZrCuAlTa metallic glass (Zr: 48-66 at %, Cu: 7-30 at %, Al: 8-12 at % and Ta: 5-18 at %), a ZrCuAlAg metallic glass (Zr: 48-66 at %, Cu: 7-30 at %, Al: 8-12 at % and Ag: 5-18 at %), a ZrCuAlNiTi metallic glass (Zr: 55-66 at %, Cu: 10-27 at %, Al: 8-12 at %, Ni: 8-14 at % and Ti: 2-5 at %), a ZrAlCuTiBe metallic glass (Zr: 37-55 at %, Cu: 10-20 at %, Al: 8-10 at %, Ti: 10-14 at % and Be: 12-25 at %), a ZrCuAlNiSi metallic glass (Zr: 55-66 at %, Cu: 25-30 at %, Al: 11-18 at %, Ni: 5-10 at % and Si: 0.5-1 at %), a ZrCuAlNiNb metallic glass (Zr: 55-66 at %, Cu: 10-27 at %, Al: 8-12 at %, Ni: 8-14 at % and Nb: 6-12 at %), a ZrHfTiCuNiAl metallic glass (Zr: 40-45 at %, Hf: 8-11 at %, Ti: 2-5 at %, Cu: 10-18 at %, Ni: 10-15 at % and Al: 5-10 at %) or a ZrTiCuNiBeYMg metallic glass (Zr: 40-45 at %, Ti: 10-15 at %, Cu: 11-18 at %, Ni: 11-15 at %, Be: 22-26.5 at %, Y: 1-2 at % and Mg: 0.5-1 at %).

In one embodiment of this disclosure, the titanium-based metallic glass comprises 23-53 at % titanium. For example, the titanium-based metallic glass may comprise a TiZrCuNbCo metallic glass (Ti: 42-50 at %, Zr: 18-24 at %, Cu: 20-30 at %, Nb: 3-5 at % and Co: 1-8 at %), a TiZrCuNi metallic glass (Ti: 32-40 at %, Zr: 7-15 at %, Cu: 20-35 at % and Ni: 3-18 at %), a TiNiCuSnBe metallic glass (Ti: 42-50 at %, Ni: 18-24 at %, Cu: 20-30 at %, Sn: 3-5 at % and Be: 1-8 at %), a TiZrHfNiCu metallic glass (Ti: 23-28 at %, Zr: 21-26 at %, Hf: 16-21 at %, Ni: 11-16 at % and Cu: 9-14 at %), a TiCuNiSiB metallic glass (Ti: 42-50 at %, Cu: 18-24 at %, Ni: 20-30 at %, Si: 3-12 at % and B: 1-2 at %), a TiZrNiCuBe metallic glass (Ti: 40-45 at %, Zr: 18-25 at %, Ni: 15-25 at %, Cu: 9-25 at % and Be: 3-7 at %) or a TiCuNiZrAlSiB metallic glass (Ti: 50-53 at %, Cu: 20-27 at %, Ni: 13-24 at %, Si: 3-5 at % and B: 1-2 at %).

In one embodiment of this disclosure, the palladium-based metallic glass comprises 40-82 at % palladium. For example, the palladium-based metallic glass may comprise a PdCuSi metallic glass (Pd: 56-82 at %, Cu: 2-27 at % and Si: 15-17 at %), a PdNiP metallic glass (Pd: 40-42 at %, Ni: 40-42 at % and P: 16-20 at %) or a PdNiCuP metallic glass (Pd: 40-50 at %, Ni: 7-15 at %, Cu: 20-35 at % and P: 10-20 at %).

In one embodiment of this disclosure, the iron-based metallic glass comprises 30-67 at % iron. For example, the iron-based metallic glass may comprise an FeCoSmB metallic glass (Fe: 60-67 at %, Co: 7-10 at %, Sm: 2-4 at % and B: 20-25 at %), an FeCoTbB metallic glass (Fe: 61-67 at %, Co: 7-10 at %, Tb: 2-4 at % and B: 20-25 at %), an FeCoNdDyB metallic glass (Fe: 61-67 at % Co: 7-10 at %, Nd: 2-4 at %, Dy: 0.5-1 at % and B: 20-25 at %), an FeCoNiZrB metallic glass (Fe: 60-67 at %, Co: 7-10 at %, Ni: 2-4 at %, Zr: 0.5-1 at % and B: 20-25 at %), an FeCoNiSiB metallic glass (Fe: 30-40 at %, Co: 25-30 at %, Ni: 8-15 at %, Si: 5-8 at % and B: 15-25 at %), a FeZrCoMoWB metallic glass (Fe: 25-30 at %, Zr: 15-25 at %, Co: 6-10 at %, Mo: 3-8 at %, W: 15-25 at % and B: 10-22 at %) or a FeCrMoErCB metallic glass (Fe: 48-56 at %, Cr: 5-15 at %, Mo: 14-18 at %, Er: 1-3 at %, C: 12-15 at % and B: 2-12 at %).

In one embodiment of this disclosure, the copper-based metallic glass comprises 40-65 at % copper. For example, the copper-based metallic glass may comprise a CuHfTi metallic glass (Cu: 50-60 at %, Hf: 15-30 at % and Ti: 10-25 at %), a CuZrAl metallic glass (Cu: 50-60 at %, Zr: 15-30 at % and Al: 10-25 at %), a CuZrNb metallic glass (Cu: 52-57 at %, Zr: 40-45 at % and Nb: 1-3 at %), a CuZrAlAg metallic glass (Cu: 48-65 at %, Zr: 23-35 at %, Al: 7-20 at % and Ag: 2-20 at %), a CuZrTiNi metallic glass (Cu: 40-48 at %, Zr: 11-20 at %, Ti: 27-34 at % and Ni: 5-8 at %), a CuZrAlY metallic glass (Cu: 40-48 at %, Zr: 40-45 at %, Al: 5-10 at % and Y: 2-5 at %), a CuZrAlTi metallic glass (Cu: 50-60 at %, Zr: 15-20 at %, Al: 5-8 at % and Ti: 12-25 at %) or a CuZrHfTi metallic glass (Cu: 50-60 at %, Zr: 15-20 at %, Hf: 8-15 at % and Ti: 8-15 at %).

In one embodiment of this disclosure, the nickel-based metallic glass comprises 35-65 at % nickel. For example, the nickel-based metallic glass may comprise a NiZrAl metallic glass (Ni: 55-57 at %, Zr: 28-35 at % and Al: 8-17 at %), a NiNbTa metallic glass (Ni: 55-60 at %, Nb: 25-30 at % and Ta: 10-20 at %), a NiNbSn metallic glass (Ni: 55-60 at %, Nb: 32-40 at % and Sn: 5-10 at %), a NiNbHfTi metallic glass (Ni: 57-62 at %, Nb: 8-20 at %, Hf: 5-10 at % and Ti: 15-20 at %), a NiZrAlNb metallic glass (Ni: 57-62 at %, Nb: 13-25 at %, Al: 3-5 at % and Ti: 15-20 at %), a NiZrTiAl metallic glass (Ni: 45-57 at %, Zr: 20-27 at %, Ti: 16-20 at % and Al: 5-8 at %), a NiZrTiPd metallic glass (Ni: 55-57 at %, Zr: 20-25 at %, Ti: 10-18 at % and Al: 3-10 at %), a NiNbTiZr metallic glass (Ni: 57-62 at %, Nb: 8-25 at %, Ti: 15-20 at % and Zr: 3-10 at %), a NiCuZrTiAl metallic glass (Ni: 35-45 at %, Cu: 5-15 at %, Zr: 25-35 at %, Ti: 5-10 at % and Al: 8-15 at %), a NiCuZrTiAlSi metallic glass (Ni: 35-45 at %, Cu: 5-15 at %, Zr: 25-35 at %, Ti: 5-10 at %, Al: 8-15 at % and Si: 0.5-1 at %) or a NiNbCrMoPB metallic glass (Ni: 60-65 at %, Nb: 2-10 at %, Cr: 2-9 at %, Mo: 3-11 at %, P: 8-19 at % and B: 2-11 at %).

In one embodiment of this disclosure, the aluminium-based metallic glass comprises 68-85 at % aluminium. For example, the aluminium-based metallic glass may comprise an AlNiMm metallic glass (Al: 68-70 at %, Ni: 20-22 at % and Mm: 8-12 at %), an AlNiY metallic glass (Al: 75-85 at %, Ni: 5-20 at % and Y: 5-12 at %), a AlVM metallic glass (Al: 68-70 at %, V: 20-22 at % and M: 8-12 at %), an AlNiCe metallic glass (Al: 68-70 at %, Ni: 20-22 at % and Ce: 8-12 at %), a AlCoY metallic glass (Al: 68-70 at %, Co: 20-22 at % and Y: 8-12 at %), an AlNiYZrCo metallic glass (Al: 75-80 at %, Ni: 6-15 at %, Y: 6-8 at %, Zr: 1-2 at %, Co: 2-4 at %) or an AlNiYCoCu metallic glass (Al: 75-80 at %, Ni: 6-15 at %, Y: 6-8 at %, Co: 2-4 at % and Cu: 1-2 at %).

In one embodiment of this disclosure, the tungsten-based metallic glass comprises 50-55 at % tungsten. For example, the tungsten-based metallic glass may comprise a WNiB metallic glass (W: 50-55 at %, Ni: 25-27 at % and B: 20-25 at %) or a WZrSi metallic glass (W: 50-55 at %, Ni: 25-27 at % and Si: 20-25 at %).

In one embodiment of this disclosure, the magnesium-based metallic glass comprises 60-80 at % magnesium. For example, the magnesium-based metallic glass may comprise a MgCuY metallic glass (Mg: 60-65 at %, Cu: 25-30 at % and Y: 8-15 at %), a MgNiNd metallic glass (Mg: 75-80 at %, Ni: 10-18 at % and Nd: 7-15 at %), a MgCuGd metallic glass (Mg: 60-65 at %, Cu: 25-30 at % and Gd: 8-15 at %), a MgAlCuY metallic glass (Mg: 60-65 at %, Al: 8-10 at %, Cu: 20-25 at % and Y: 5-10 at %), a MgCuYSi metallic glass (Mg: 60-65 at %, Cu: 23-30 at %, Y: 8-10 at % and Si: 1-2 at %), a MgCuZnY metallic glass (Mg: 60-65 at %, Cu: 23-30 at %, Zn: 1-2 at % and Y: 8-10 at %) or a MgCuNiZnAgY metallic glass (Mg: 60-65 at %, Cu: 5-10 at %, Ni: 5-10 at %, Zn: 3-9 at %, Ag: 3-5 at % and Y: 8-10 at %).

Here, the nanotube array structure 20 may provide a larger surface area than a planar structure, and the nanotube 21 may contain air. The amount of air contained in the nanotube array structure 20 is changeable according to the diameter of the nanotube 21. A greater amount of air contained in the nanotube array structure 20 can reduce an effective refractive index of transverse magnetic polarization and transverse electric polarization such that the ordered array of the nanotube array structure 20 is capable of enhancing the electromagnetic field of the waveguide mode. In addition, a diffractive reflectance intensity or a diffractive transmittance intensity of the nanotube array structure 20 for transverse electric polarization and transverse magnetic polarization is increased with an increase in the diameter of each nanotube 21.

The plurality of aptamers 30 are anchored in the plurality of nanotubes 21 which are processed by surface activation and interact with the target to be sensed to form a bond for subsequent analysis or sensing. In other words, one end of the aptamer 30 may be bonded to the treated surface of the nanotube 21, and the other end of the aptamer 30 may interact with the target to be sensed to form a bond. Here, the aptamers 30 may be antibodies, DNA probes, or biotins, and the aptamers 30 may be changed according to the target to be sensed by the sensor.

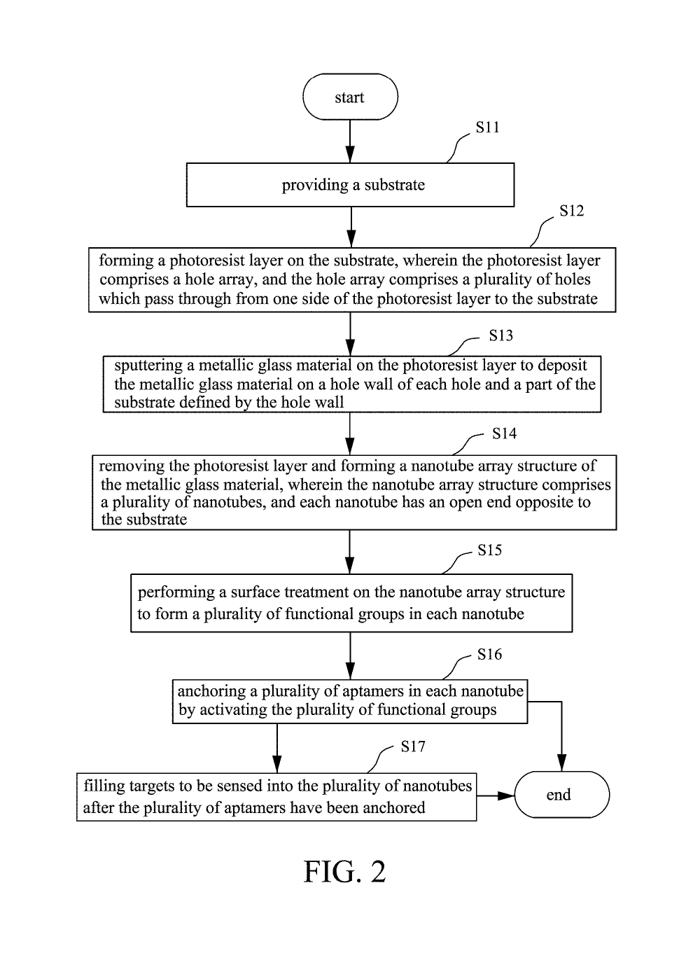

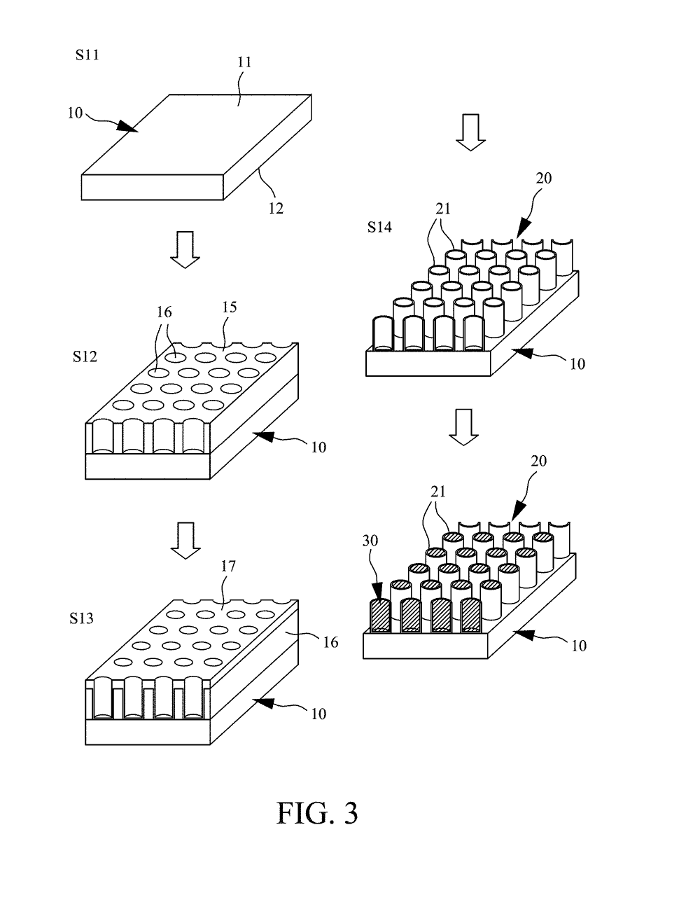

Now refer to FIG. 2 and FIG. 3. FIG. 2 illustrates a flowchart of a method of manufacturing a sensor of this disclosure, and FIG. 3 illustrates a structural configuration corresponding to each step of the method of manufacturing the sensor of this disclosure. As illustrated in FIG. 2 and FIG. 3, the method of manufacturing the sensor of this disclosure comprises Steps S11 to S16, which are described in detail below.

Step S11: providing a substrate.

First, a suitable substrate 10 is provided according to the use requirements of the sensor 1 of this disclosure. Here, the substrate 10 may be a prepared sheet or block material having a fixed size. In this disclosure, the substrate 10 is a silicon wafer, but this disclosure is not limited thereto, and the substrate 10 may be any object having a surface on which a photoresist layer and a sputtered metallic glass material layer can form. The substrate 10 comprises a first side 11 and a second side 12 opposite to the first side 11. In this embodiment, the area of the substrate 10 is about 1 square centimetre, but the size of the substrate 10 of this disclosure is not limited thereto.

Step S12: forming a photoresist layer on the substrate, wherein the photoresist layer comprises a hole array, and the hole array comprises a plurality of holes which pass through from one side of the photoresist layer to the substrate.

After the substrate 10 has been provided in Step S11, the photoresist layer 15 is formed on the first side 11 of the substrate 10. In one embodiment of this disclosure, the photoresist layer 15 comprises photoresist formed on the first side 11 of the substrate 10 by spin coating. A cleaning process may be performed the substrate 10 so as to remove dust or organic contaminants on the surface, and then a hexamethyldioxane treatment may be performed to facilitate the formation of the photoresist layer 15 on the first side 11. A photolithography process may be performed on the photoresist layer 15 to form a hole array. The hole array comprises a plurality of holes 16. The plurality of holes 16 are arranged in a regular order, and each hole 16 passes through from one side of the photoresist layer 15 (i.e., the opposite side of the photoresist layer 15 in contact with the substrate 10) to the substrate 10. In this embodiment, the thickness of the photoresist layer 15 is about 780 nm, but the thickness of the photoresist layer 15 can be adjusted with the height of each nanotube of the subsequently formed nanotube array structure. In addition, the diameter of each hole 16 can also be adjusted with the diameter of each nanotube of the subsequently formed nanotube array structure.

Step S13: sputtering a metallic glass material on the photoresist layer to deposit the metallic glass material on a hole wall of each hole and a part of the substrate defined by the hole wall.

After the photoresist layer 15 has been formed in Step S12, a sputtering process is performed. The metallic glass material is sputtered on the photoresist layer 15 to form a deposition layer 17 by a sputtering target made of the metallic glass material target (for example, an alloyed target of Zr₅₅Cu₃₀Al₁₀Ni₅). The metallic glass material is deposited on a hole wall of each hole 16 and a part of the substrate 10 defined by the hole wall of each hole 16. In one embodiment of this disclosure, the sputtering process is performed by using a radio frequency magnetron sputtering system. The sputtering process is performed for about 225 to 675 seconds without intentional heating of the substrate 10 on the photoresist layer 15 by the target made of the metallic glass material, and the operating conditions for the sputtering system are set at a base pressure of about 5*10⁻⁴ mTorr and a working pressure of about 3 mTorr with a sputtering distance of 10 mm. The thickness of the deposition layer 17 of the metallic glass material on the surface of the photoresist layer 15 and the thickness of the metallic glass material formed on the hole wall of each hole 16 may be adjusted depending on the sputtering time. Under the same sputtering time, the thickness of the metallic glass material formed on the hole wall of each hole 16 may also be changed with the size of the hole 16. In other words, the thickness of the metallic glass material formed on the hole wall of each hole 16 may be reduced with an increase in the diameter of the hole 16.

Step S14: removing the photoresist layer and forming a nanotube array structure of the metallic glass material, wherein the nanotube array structure comprises a plurality of nanotubes, and each nanotube has an open end opposite to the substrate.

After the metallic glass material has been sputtered on the photoresist layer 15 in Step S13, the excess metallic glass material deposited on the photoresist layer 15 may be removed, and a rinsing process is performed with a solvent such as toluene to remove the photoresist layer 15 on the surface of the substrate 10. Therefore, the nanotube array structure 20 is formed on the substrate 10 by the remaining metallic glass material. At this moment, the nanotube array structure 20 comprises the plurality of nanotubes 21, which are connected to the substrate 10 respectively, and each nanotube 21 has an open end opposite to the substrate 10. The height of each nanotube 21 is equal to the thickness of the photoresist layer 15, and the diameter of each nanotube 21 is equal to the diameter of each hole 16 of the photoresist layer 15. For example, in this embodiment, the height of each nanotube 21 is about 780 nm, and the diameter of each nanotube 21 is about 500 nm. In addition, the wall thickness of each nanotube 21 may be adjusted by altering the sputtering time. For example, in this embodiment, the wall thickness of each nanotube 21 is about 100 nm, but this disclosure is not limited thereto.

Step S15: performing a surface treatment on the nanotube array structure to form a plurality of functional groups in each nanotube.

After the photoresist layer 15 has been removed and the nanotube array structure 20 has been formed by the metallic glass material in Step S14, the surface treatment for the nanotube array structure 20 may be performed to form a plurality of functional groups, such as an amino group (—NH₂), a carboxyl group (—COOH) or other functional groups, which can bond with targets to be sensed in each nanotube 21. In one embodiment of this disclosure, a modified medium is created by adding 3-aminopropyltriethoxysilane (APTES) to a methanol solution. When the surface treatment is performed, an inner surface of each nanotube 21 is modified by the methanol solution comprising 3-aminopropyltriethoxysilane to form the plurality of functional groups. One end of APTES is a silane group for bonding with the oxygen molecules on the surface of the nanotube 15, and the other end of APTES is an amine group for interacting with the target to be sensed, such that the surface of the nanotube 15 may be modified by APTES. The concentration of APTES in the methanol solution is about 0.1 wt % to 10 wt %, and the preferred range is 0.1 wt % to 5 wt %. The concentration of APTES is related to a reaction time of the oxygen molecules on the surface of the nanotube 15. If the concentration of APTES is too low (for example, less than 0.1 wt %), the processing time must be extended, which will increase the manufacturing cost; if the concentration of APTES is too high (for example, more than 10 wt %), the nanotube 15 may be obstructed by APTES and the subsequent sensing effect thereby reduced.

Step S16: anchoring a plurality of aptamers in each nanotube by activating the plurality of functional groups.

After the surface treatment for the nanotube array structure 20 has been performed in Step S15, the activating process may be performed for the plurality of functional groups, such that the plurality of aptamers 30 are anchored in each nanotube 15 when the aptamers 30 contact the activated functional groups. In one embodiment of this disclosure, the plurality of functional groups on the surface of each nanotube 15 are activated by adding a solution containing 1-ethyl-3-(3-dimethylaminopropyl) carbodiimide (EDC) and N-hydroxysuccinimide (NHS), and then a phosphate buffered saline (PBS) buffer solution comprising the plurality of aptamers is added to the solution and the solution is sufficiently shaken and mixed such that the plurality of aptamers are combined with the plurality of functional groups to anchor in each nanotube 15. The concentration of the plurality of aptamers in the PBS buffer solution is about 2 wt % to 20 wt %.

Subsequently, an alloyed target of Zr₅₅Cu₃₀Al₁₀Ni₅ is sputtered at a rate of 800 nm/hour for 450 seconds to produce a semi-finished product. A planar deposition layer of metallic glass material directly sputtered on the silicon wafer 10 (i.e., without forming the photoresist layer on the silicon wafer 10) is used as the comparative example A, and another semi-finished product of the sensor 1 made by the steps S11 to S14 of the method of manufacturing the sensor of this disclosure is used as the experimental example B. The nanotube array structure 20 of metallic glass material is also formed by using an alloyed target of Zr₅₅Cu₃₀Al₁₀Ni₅ and sputtering at a rate of 800 nm/hour for 450 seconds. Then, for the comparative example A and the experimental example B, the structural surfaces of the metallic glass material are modified by the methanol solution containing about 5 wt % APTES, and after activating the plurality of functional groups, the PBS buffer solution containing about 132 μL of biotins (1 mg/mL) is used for combining the plurality of functional groups with the biotins such that the biotins are anchored on the structural surfaces of the metallic glass material of the comparative example A and the experimental example B. Experimental results have shown that the concentration of the biotins measured with the experimental example B on the surface of the nanotube array structure 20 is about 161.23 μg/cm², while the concentration of the biotins measured with the comparative example A on the surface of the planar deposition layer of the metallic glass material is about 12.81 μg/cm². Accordingly, these concentrations are sufficient to demonstrate that the sensor 1 of this disclosure can provide a larger surface area due to the nanotube array structure 20 of the metallic glass material than can the comparative example without any nanotube array structure 20. Therefore, a larger quantity of aptamers is anchored on the sensor 1 of this disclosure to improve the sensing effect of the sensor 1.

As illustrated in FIG. 2 again, in this embodiment, the method of manufacturing the sensor of this disclosure further comprises Step S17 after Step S16: filling targets to be sensed into the plurality of nanotubes after the plurality of aptamers have been anchored.

After the plurality of aptamers have been anchored in Step S16, the sensor 1 of this disclosure may be placed in an environment to be sensed and bond with the targets to be sensed by the plurality of aptamers for subsequent sensing and analysis. However, to obtain the analytical data for comparison, the targets to be sensed with a predetermined concentration or/and type are filled into the plurality of nanotubes 21 after the plurality of aptamers tubes 21 of the sensor 1 of this disclosure have been anchored to the plurality of aptamers. The aptamers in the nanotube 21 interact with the target to be sensed and bond together such that the target to be sensed remains in the nanotube 21. Thereafter, an optical test may be performed on the sensor 1 of this disclosure, and the test results corresponding to the target to be sensed under different conditions may be collected as a basis for comparison and analysis. In this embodiment, the targets to be sensed may be biomacromolecules.

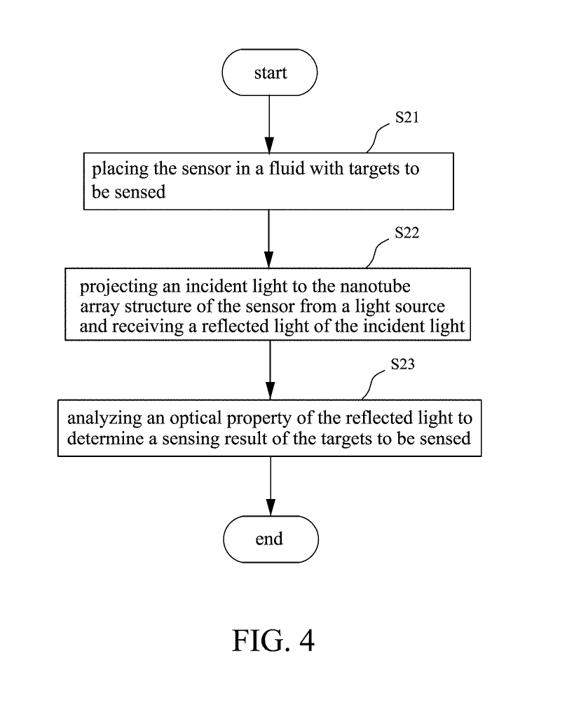

This disclosure further comprises the sensing method of the sensor 1. Please refer to FIG. 4, which illustrates a flowchart of the sensing method of this disclosure. As illustrated in FIG. 4, the sensing method of this disclosure comprises Steps S21 to S23, which are described in detail below.

Step S21: placing the sensor in a fluid with targets to be sensed.

For example, the sensor 1 of this disclosure may be placed in a fluid (such as a gas or a solution) having targets to be sensed, and the targets to be sensed may enter the plurality of nanotubes 21 by the flow motion of the fluid. The anchored plurality of aptamers bond with the targets to be sensed in the nanotubes 21.

Step S22: projecting an incident light to the nanotube array structure of the sensor from a light source and receiving a reflected light of the incident light.

After Step S21 has been performed, an optical test may be performed on the sensor 1. An incident light is projected from one side of the sensor 1 to the nanotube array structure of the sensor 1 by a light source and a reflected light of the incident light is received from the other side of the sensor 1. The light source may be different types of light sources, such as visible light, ultraviolet light, and infrared light, and the wavelength of the light source may range from 200 nm to 4000 nm.

Step S23: analyzing an optical property of the reflected light to determine a sensing result of the targets to be sensed.

After Step S22 has been performed, the optical property obtained by analyzing the reflected light is compared with the test analysis data previously stored in the database, and the type, concentration or other relevant information of the target sensed by the sensor 1 is determined. Here, the optical property may be associated with a reflection angle of the reflected light with maximum reflectivity, a color of the reflected light, or the like.

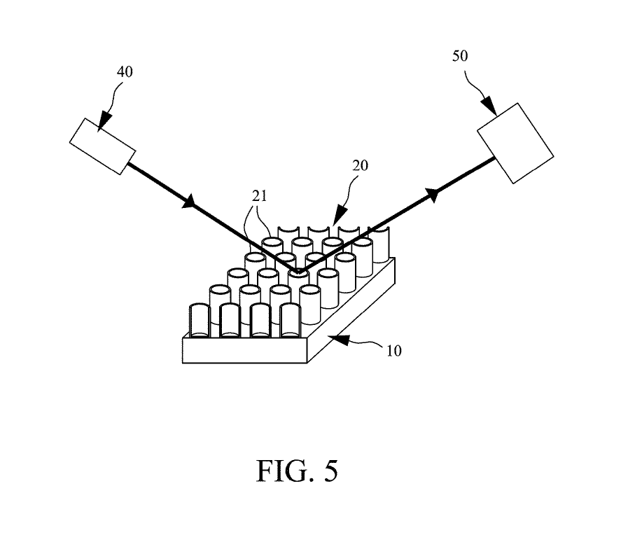

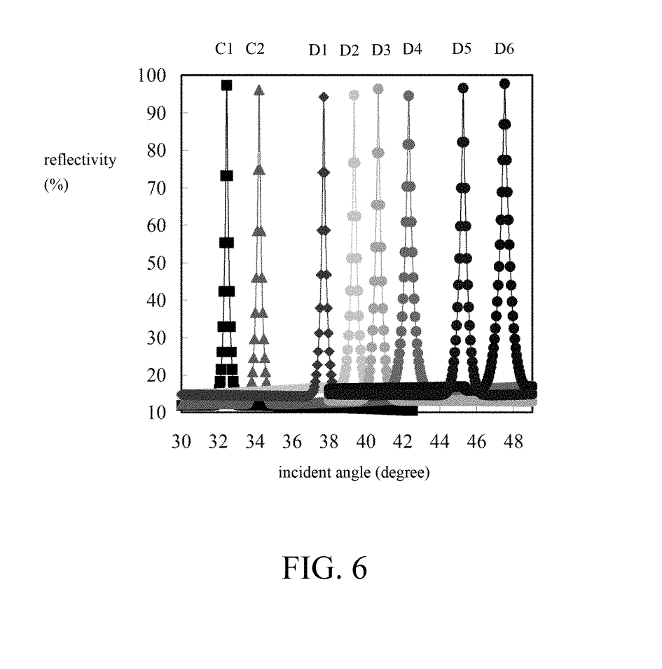

Refer to FIG. 5 and FIG. 6. FIG. 5 illustrates an embodiment of the sensing method of this disclosure, and FIG. 6 illustrates incident angles of light and reflectances corresponding to different comparative examples and experimental examples measured by the sensing method of this disclosure. In the following experiments, the semi-finished products of the sensor 1 made by the steps S11 to S14 of the method of manufacturing the sensor of this disclosure are used as comparative examples C1 and C2. The comparative example C1 is placed in a flowing atmospheric environment, and the comparative example C2 is placed in a flowing water environment. The sensors 1 made by the steps S11 to S16 of the method of manufacturing the sensor of this disclosure are used as the experimental examples D1 to D6, and the experimental examples D1 to D6 are all placed in the flowing water environment. A 25 nM streptavidin is injected at a rate of 10 μL/min into the water environment of the experimental example D2, a 50 nM streptavidin is injected at a rate of 10 μL/min into the water environment of the experimental example D3, a 75 nM streptavidin is injected at a rate of 10 μL/min into the water environment of the experimental example D4, a 100 nM streptavidin is injected at a rate of 10 μL/min into the water environment of the experimental example D5, and a 125 nM streptavidin is injected at a rate of 10 μL/min into the water environment of the experimental example D6. Then, as illustrated in FIG. 5, an incident light is projected to any one of the nanotube array structures 20 of the comparative examples C1 to C2 and the experimental examples D1 to D6 from one side by a light source 40, and a reflected light of the incident light is received from the opposite side through the analyzer 50. An incident angle of the incident light may be adjusted to analyze the incident angle with the maximum reflectance in the TE polarization and TM polarization waveguide modes for each example (i.e., the maximum reflection angles). The diameters of the nanotubes of the nanotube array structures 20 of the comparative examples C1 to C2 and the experimental examples D1 to D6 are all 500 nm, and the light source is a He—Ne laser light source.

As illustrated in FIG. 6, taking the P-polarized light excited TM polarized optical waveguide mode as an example, according to the experimental results, each nanotube of the nanotube array structure of the comparative example C1 is only filled with air, and the incident angle with the maximum reflectivity is about 32.65°. Each nanotube of the nanotube array structure of the comparative example C2 is filled with water, and the incident angle with the maximum reflectivity may be increased to about 34.3°. After the surface of each nanotube of the nanotube array structure of the experimental example D1 is modified and the biotins are anchored, the incident angle with the maximum reflectivity may be increased to about 37.25°. After the 25 nM streptavidin bonds with the biotins in each nanotube of the nanotube array structure of the experimental example D2 to fill into the nanotube, the incident angle with the maximum reflectance may be increased to about 39.5°. With the increase in the concentration of streptavidin, the incident angle with the maximum reflectance of any of the experimental examples D3 to D6 as compared with the experimental example D2 shows an increasing trend. Accordingly, for the purpose of sensing streptavidin, as long as the relevant angle data are collected, the concentration of streptavidin may be detected according to the different incident angle of the P-polarized light having the maximum reflectance measured by the sensor of this disclosure. Similarly, the relevant angle data may be collected in a similar manner for different targets to be sensed for corresponding sensing.

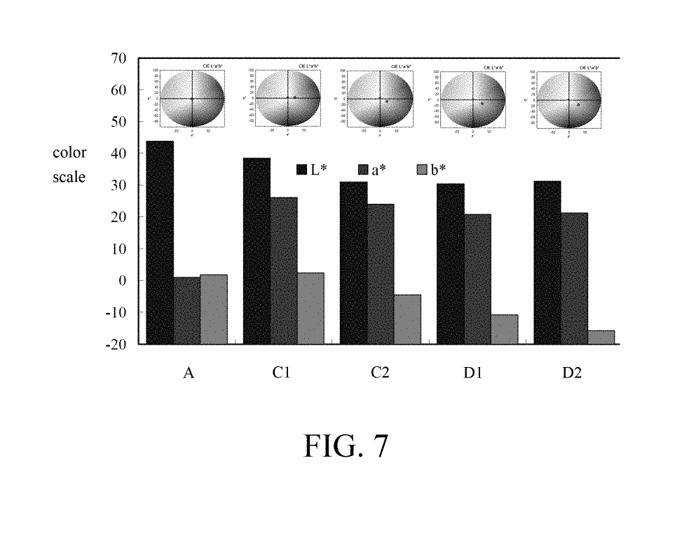

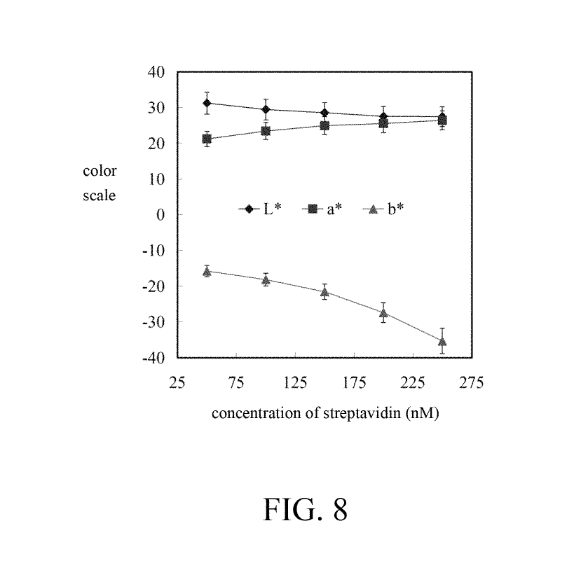

In addition to the aforementioned incident angle with the maximum reflectance of the reflected light as the sensing basis, the sensor 1 of this disclosure may also sense targets to be sensed by analyzing a color of the reflected light. Please refer to FIG. 7 and FIG. 8. FIG. 7 illustrates chromaticity of the reflected light corresponding to different comparative examples and experimental examples measured by the sensing method of this disclosure, and FIG. 8 illustrates chromaticity of the reflected light corresponding to different concentrations of streptavidin measured by the sensing method of this disclosure. Based on the aforementioned comparative examples A, C1 and C2 and experimental examples D1 and D2, an incident light is projected from one side of the nanotube array structure 20 of any of the comparative examples A, C1 and C2 and experimental examples D1 and D2 by a light source 40, and a reflected light of the incident light is received by the analyzer 50 on the opposite side. The color of the reflected light is measured and analyzed under the condition that the incident angle is fixed. The incident angle of the incident light is fixed at 8°.

In this experiment, multiple color variations are defined by using the L*a*b* color space and the a*b* coordinates of the uniform chromaticity diagram proposed by the Commission Internationale de l'Éclairage (CIE) in 1976. As illustrated in FIG. 7, according to experimental results, the reflected light reflected by the deposition layer of the planar metallic glass material of the comparative example A does not show any surface color and maintains the original white light. For the comparative examples C1-C2 and the experimental examples D1-D2, the refractive index of the reflected light is changed and shows different color changes from the original white light to purple light because the surface has the nanotube array structure of the metallic glass material and different media filled in each nanotube and on the surface of the nanotube array structure. Accordingly, by analyzing the difference in the color ratios measured by the reflected light, it may be determined whether the sensor of this disclosure has sensed the targets.

As illustrated in FIG. 8, for the purpose of sensing streptavidin, as the concentration of streptavidin increases, the chromaticity L* decreases slightly, and the chromaticity a* increases slightly, but the chromaticity b* decreases obviously. Accordingly, as long as the color data associated with the reflected light are collected, the concentration of streptavidin can be detected according to the color of the reflected light measured by the sensor of this disclosure. Similarly, for different targets to be sensed, the color data associated with the reflected light can also be collected in a similar manner for corresponding sensing.

In addition to the aforementioned reflected light of the incident light as the sensing basis, the sensor 1 of this disclosure may also sense targets to be sensed by analyzing a transmitted light of the incident light. Given a transparent substrate, an incident light is projected from one side of the nanotube array structure by a light source, and a transmitted light of the incident light passing through the nanotube array structure and the substrate is received by the analyzer on the opposite side. For the purpose of sensing streptavidin, as the concentration of streptavidin increases, the transmittance intensity of the transmitted light decreases. Accordingly, as long as the data associated with the transmitted light are collected, the concentration of streptavidin can be detected according to the transmitted light measured by the sensor of this disclosure.

In summary, the sensor 1 of this disclosure is capable of generating reactions with selectivity, sensitivity, and reproducibility in response to the environment according to the nanotube array structure 20 of the metallic glass material. It is advantageous to the sensing of a target. The manufacturing processes of the sensor 1 of this disclosure are simple and the manufacturing cost may be effectively reduced.

The above detailed description is merely illustrative in nature and is not intended to limit the embodiments of the subject matter or the application and uses of such embodiments. Moreover, while at least one exemplary embodiment has been presented in the foregoing detailed description, it should be appreciated that a vast number of variations exist. It should also be appreciated that the exemplary one or more embodiments described herein are not intended to limit the scope, applicability, or configuration of the claimed subject matter in any way. Rather, the foregoing detailed description will provide those skilled in the art with a convenient guide for implementing the described one or more embodiments. Also, various changes can be made in the function and arrangement of elements without departing from the scope defined by the claims, which include known equivalents and foreseeable equivalents at the time of filing this patent application.

What is claimed is:

1. A sensor, comprising:
a substrate;
a nanotube array structure formed on one side of the substrate, the nanotube array structure comprising a plurality of nanotubes, each nanotube having an open end opposite to the substrate; and
a plurality of aptamers anchored in the plurality of nanotubes, which are processed by surface activation.

2. The sensor of claim 1, wherein a wall thickness-to-diameter ratio of each nanotube ranges from 1:2 to 1:10.

3. The sensor of claim 1, wherein a height-to-width ratio of each nanotube ranges from 1:0.5 to 1:10.

4. The sensor of claim 1, wherein a duty ratio of the plurality of nanotubes ranges from 0.5 to 6.

5. The sensor of claim 1, wherein the nanotube array structure comprises an ordered array composed of the plurality of nanotubes, and a diameter of each nanotube ranges from 10 nm to 100 μm.

6. The sensor of claim 1, wherein a diffractive reflectance intensity or a diffractive transmittance intensity of the nanotube array structure for transverse electric polarization and transverse magnetic polarization is increased with an increase in a diameter of each nanotube.

7. The sensor of claim 1, wherein the nanotube array structure comprises at least one material selected from the group consisting of: a zirconium-based metallic glass, a titanium-based metallic glass, a palladium-based metallic glass, an iron-based metallic glass, a copper-based metallic glass, a nickel-based metallic glass, an aluminium-based metallic glass, a tungsten-based metallic glass, and a magnesium-based metallic glass.

8. A method of manufacturing a sensor, comprising:
providing a substrate;
forming a photoresist layer on the substrate, wherein the photoresist layer comprises a hole array, and the hole array comprises a plurality of holes which pass through from one side of the photoresist layer to the substrate;
sputtering a metallic glass material on the photoresist layer to deposit the metallic glass material on a hole wall of each hole and a part of the substrate defined by the hole wall;
removing the photoresist layer and forming a nanotube array structure of the metallic glass material, wherein the nanotube array structure comprises a plurality of nanotubes, and each nanotube has an open end opposite to the substrate;
performing a surface treatment on the nanotube array structure to form a plurality of functional groups in each nanotube; and
anchoring a plurality of aptamers in each nanotube by activating the plurality of functional groups.

9. The method of claim 8, wherein an inner surface of each nanotube is modified by a solution of 0.1 wt % to 10 wt % 3-aminopropyltriethoxysilane in methanol to form the plurality of functional groups when the surface treatment is performed.

10. The method of claim 9, wherein the plurality of functional groups are activated by a solution containing 1-ethyl-3-(3-dimethylaminopropyl)carbodiimide and N-hydroxysuccinimide, and the plurality of aptamers are combined with the plurality of functional groups by adding a 2 wt % to 20 wt % buffer solution of the plurality of aptamers.

11. The method of claim 8, wherein the plurality of aptamers are antibodies, DNA probes, or biotins.

12. The method of claim 8, further comprising:
filling targets to be sensed into the plurality of nanotubes after the plurality of aptamers have been anchored.

13. A sensing method for the sensor as claimed in claim 1, comprising:
placing the sensor in a fluid with targets to be sensed;
projecting an incident light to the nanotube array structure of the sensor from a light source and receiving a reflected light of the incident light; and
analyzing an optical property of the reflected light to determine a sensing result of the targets to be sensed.

14. The method of claim 13, wherein the optical property is associated with a reflection angle of the reflected light with maximum reflectivity.

15. The method of claim 13, wherein the optical property is associated with a color of the reflected light.
